(19) United States
(12) Patent Application Publication
(10) Pub. No.: US 2009/0169023 A1
(43) Pub. Date: Jul. 2, 2009

(54) METHOD FOR CONTROLLING VOLUME OF A MULTIMEDIA PLAYER

(76) Inventor: Ching-Chieh Wang, Yilan County (TW)

Correspondence Address: NORTH AMERICA INTELLECTUAL PROPERTY CORPORATION, P.O. BOX 506, MERRIFIELD, VA, 22116, US

(21) Appl. No.: 11/965,727

(22) Filed: Dec. 27, 2007

(51) Int. Cl. H04R 29/00; H03G 3/20

(52) U.S. Cl. 381/57; 381/56

(57) ABSTRACT

A method for controlling volume of a multimedia player includes receiving a parameter having no volume control information; comparing the parameter with a predetermined condition to determine a volume level; and setting initial volume according to the volume level.

### BACKGROUND OF THE INVENTION

1. Field of the Invention

The present invention relates to a method for controlling volume of a multimedia player, and more particularly to a volume control method for determining initial volume of a multimedia player.

2. Description of the Prior Art

US patent with application number 20050226442 discloses a temporal volume control device, comprising an audio output component for receiving information corresponding to a temporal ambient noise map and producing an audio volume level substantially corresponding to and greater than said temporal ambient noise map, said temporal ambient noise map comprising at least one ambient noise value corresponding to a time value for at least one period of time.

Another automatic volume control method for a TV set disclosed in US patent 20070076131 utilizes a communication interface to receive an incoming call and a voltage change signal, and a volume control unit adjusts the volume of the TV set according to the incoming call or voltage change signal. For example, when the viewer receive a telephone call, a TV set connected to a telephone can lower the volume to a predetermined answering volume, when the viewer ring off the phone, the TV set can reinstate the volume of the TV set to the pre-answering volume.

### SUMMARY OF THE INVENTION

An embodiment of a method for controlling volume of a multimedia player comprises receiving a parameter having no volume control information; comparing the parameter with a predetermined condition to determine a volume level; and setting initial volume based on the volume level.

Another embodiment discloses a method for controlling volume of a multimedia player, which comprises setting initial volume when turning on the multimedia playing system; and automatically displaying an adjusting user interface on the display screen of the multimedia player for the user to adjust the volume.

Still another embodiment of the present invention discloses a method for controlling volume of a multimedia player, which comprises: setting a predetermined parameter before the multimedia player is powered on; and setting the power on volume of the multimedia player according to the predetermined parameter.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart illustrating a method for controlling volume of a multimedia player according to a first embodiment.

FIG. 2 is a flow chart illustrating a method for controlling volume of a multimedia player according to a second embodiment.

FIG. 3 is a flow chart illustrating a method for controlling power-on volume of a multimedia player according to an embodiment.

### DETAILED DESCRIPTION

Most televisions, portable DVD players, radio stations, personal digital assistant (PDA), and other multimedia players do not have special controlling mechanism for determining the volume of the speaker immediately after turning on the machine. The power-on volume is typically maintained as the same as the volume of the machine when it is being switched off. People are often startled by unexpected high volume when the multimedia playing system is powered on, especially in quiet places or late at night.

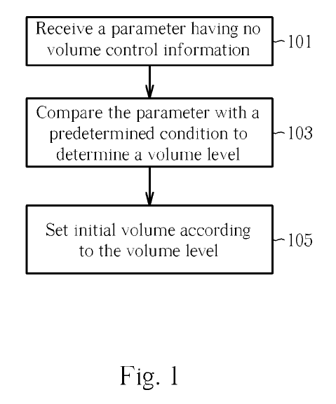

FIG. 1 is a flow chart illustrating a method for controlling volume of a multimedia player according to a first embodiment of the present invention. The multimedia player may be a television, portable DVD player, radio station, personal digital assistant (PDA), and etc. The multimedia player receives a parameter having no volume control information (Step 101), and compares the parameter with a predetermined condition to determine a volume level (Step 103). The predetermined condition may represent a value or a range of the parameter which can be used to determine a volume level of the multimedia player. The multimedia player sets initial volume according to the volume level (Step 105).

In some embodiments, the initial volume of the multimedia player is the volume of the speaker when the multimedia player is initially turned on (power-on volume). In some other embodiments, the initial volume may be the volume of the speaker immediately after switching from one channel to another channel. The parameter in step 103 can be a time parameter, a program parameter, a user behavior parameter, or an environment parameter.

A time parameter, for example, retrieved from an internal clock, may be used to indicate the time at which the multimedia player is powered on, or switching to a new channel. In this embodiment, the initial volume is set according to the powered-on time. For example, if the time parameter indicates the user turned the multimedia player at 01:00 AM, a suitable volume level for night viewing is determined by comparing the time parameter with the stored predetermined condition. A control signal may be generated to decrease or increase the volume to suitable volume. If the time parameter is 02:00 PM, the initial volume is set to an appropriate daytime level.

A look-up table may be used to stores a plurality of predetermined conditions so that a volume level can be found by searching the look-up table with a time parameter. Users of the multimedia player may be able to manage the look-up table by adding, deleting, or modifying entries of the look-up table through a user interface.

A program parameter indicates the kinds of programs currently played by the multimedia player. In this embodiment, the initial volume may be set according to the current program type when the multimedia player is powered on or switched to a new channel. For example, if the program played by the multimedia player is a sports program, the volume could be decreased because such program may be excessively noisy. And if the program played by the multimedia player is a news program, then the volume can be increased because the contents might be important and should be heard clearly.

User behavior parameters indicate customize conditions set by users of the multimedia player. The users may input a particular volume setting for a particular person in the family, for example, the grandfather needs to turn the volume up. Thus if the user behavior parameter indicates that the grand father is using the multimedia player, the volume can be increased to accommodate his hearing.

Environment parameters are parameters indicating the ambient environment surrounding the multimedia player. In an embodiment, the environment parameter indicates a noise level and step 101 further comprises detecting a noise level of the surrounding environment to generate the environment parameter. The initial volume of the multimedia player may set to a high volume level if the multimedia player detects and judges the surrounding environment is noisy. Some other exemplary environment parameters are radio signal, electromagnetic signal, and temperature. According to above-mentioned methods, the volume of the multimedia player can be adjusted without directly inputting a volume controlling command. If such a method is utilized for controlling the power-on volume, it may prevent the user from being startled by high initial volume. Comparing with the prior art which can only control the volume after the system is powered on, embodiments of the present invention may control the power-on volume.

If the environment parameter indicates a strong electromagnetic signal existed near the multimedia player, the initial volume of the multimedia player can be set to a relatively low volume level. In some embodiments, the multimedia player may display a warning message such as an icon or a sentence on the display screen to notify the user the coming of a mobile phone call, email, or short message. By this way, the multimedia player is not needed to connect the telephone, and can detect text messages besides phone calls.

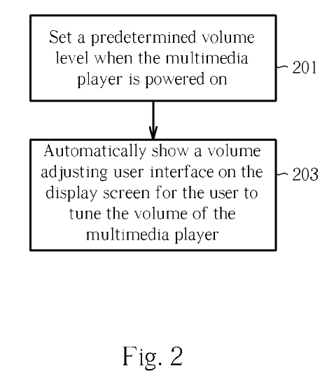

FIG. 2 is a flow chart illustrating another embodiment of the volume control method for a multimedia player. The method comprises setting a predetermined volume level when the multimedia player is powered on (step 201), and automatically showing a volume adjusting user interface on the display screen for the user to tune the volume of the multimedia player (step 203).

In this way, since the power-on volume can be preset to a quiet volume level, the user will not be startled when the multimedia player is powered on, and the control interface will automatically appear on the screen to remind the user to adjust the volume if needed.

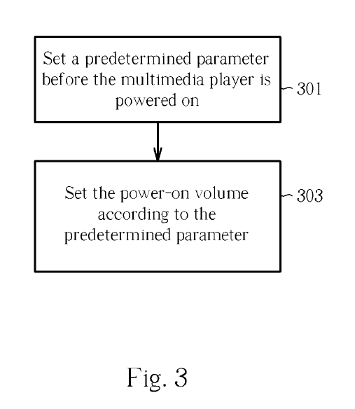

FIG. 3 is a flow chart illustrating an embodiment of the volume control method for the multimedia player. The method shown in FIG. 3 comprises setting a predetermined parameter before the multimedia player is powered on (step 301), and setting the power-on volume according to the predetermined parameter (step 303). In an embodiment, a remote controller transmits a predetermined parameter to control the power-on volume before turning the multimedia player on, thus the user can set the power-on volume without powering on the multimedia player. The predetermined parameter indicates a power-on volume level.

According to above-mentioned embodiments, the volume of the multimedia player can be preset or adjusted without directly inputting a volume controlling command when it is powered on.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for controlling volume of a multimedia player, comprising:
(a) receiving a parameter having no volume control information;
(b) comparing the parameter with a predetermined condition to determine a volume level; and
(c) setting initial volume according to the volume level.

2. The method of claim 1, wherein the initial volume is the volume of the multimedia player when turning on the multimedia player.

3. The method of claim 1, wherein the initial volume is the volume of the multimedia player after switching to a new channel.

4. The method of claim 1, wherein the parameter comprises at least one of a time parameter, a program parameter, an environment parameter, and a user behavior parameter.

5. The method of claim 1, wherein the parameter indicates a noise level, and the method further comprises detecting a noise level of surrounding environment of the multimedia player.

6. The method of claim 1, wherein the parameter indicates an electromagnetic signal level, and the method further comprises detecting and measuring an electromagnetic signal.

7. The method of claim 6, further comprising showing a warning message on a display screen of the multimedia player.

8. The method of claim 1, further comprising automatically showing an adjusting user interface on a display screen of the multimedia player for requesting if volume adjustment is required.

9. A method for controlling volume of a multimedia player, comprising:
setting initial volume to a predetermined volume level when the multimedia player is powered on; and
automatically showing an adjusting user interface on a display screen of the multimedia player for requesting if volume adjustment is required.

10. The method of claim 9, wherein the initial volume is set to silence when the multimedia player is powered on.

11. A method for controlling power-on volume of a multimedia player, comprising:
receiving a predetermined parameter before the multimedia player is powered on; and
setting the power-on volume of the multimedia player according to the predetermined parameter.

12. The method of claim 11, wherein the predetermined parameter indicates a volume level.
